(19) United States
(12) Patent Application Publication
(10) Pub. No.: US 2025/0169047 A1
(43) Pub. Date: May 22, 2025

(54) FEEDER REPLACEMENT

(71) Applicant: ASMPT GmbH & Co. KG, Munich (DE)

(72) Inventors: Johannes JUSTINGER, Munich (DE); Vincent PFEIFER, Munich (DE); Fuyan YANG, Munich (DE)

(21) Appl. No.: 18/948,598

(22) Filed: Nov. 15, 2024

(30) Foreign Application Priority Data
Nov. 22, 2023 (DE) 10 2023 132 497.7

(51) Int. Cl. H05K 13/08; H05K 13/04

(52) U.S. Cl. CPC H05K 13/086; H05K 13/0434; H05K 13/085; H05K 13/046

(57) ABSTRACT

Feeders at a placement machine are replaced, automatically, according to a new protocol in which a partially-depleted feeder is temporarily moved from its slot to an external storage, a full replacement feeder is put in its slot, and the partially-depleted feeder is returned to a spare slot of the placement machine, from where its remaining components are picked.

### BACKGROUND AND PRIOR ART

This invention relates to a method for supplying SMT-components within feeder modules to a placement machine during an SMT-placement operation, and a method for replacing depleted feeder modules at a placement machine during an SMT-placement operation.

The present invention relates in general to the technical field of equipping component carriers, such as printed circuit boards (PCBs), substrates or workpieces, with electronic components in a so-called surface-mount technology (SMT) process.

The production of electronic subassemblies occurs typically with so-called placement machines, by which electronic components are removed from a component supply device in an automated manner and placed on a component carrier such as, for example, a printed circuit board. A transfer of components from the component supply device to their respective placement position occurs by means of a component handling device, for example, a so-called placement head. In most cases, such a transfer of a component occurs by means of a single handling device, commonly referred to as placement head.

The most common packaging for small electronic components uses carrier tapes, sometimes referred to as “belts”, into which small pockets are formed. In each of the pockets there is provided one component. Only one type of component is located within each carrier tape. To save space and for easier transport, the carrier tapes are conventionally formed as reels by winding on a spool. Typically, the tape reel is placed in a feeder module (usually simply referred to as a “feeder”) which includes drive means for driving the tape forward, such as a motor-driven pin-wheel which engages with holes provided along the length of the carrier tape, and a pick-up area or window which provides access to the components. The feeder can be removably inserted into a placement machine. The placement machine is provided with a number of parallel slots or tracks, each slot configured to releasably receive a feeder. In this way, a placement machine may be fitted with a plurality of different feeders, each feeder capable of supplying a particular component to the placement machine.

More recently, a cartridge system has been proposed, in which a reel is placed in a passive cartridge module or cassette, which may conveniently be a relatively inexpensive plastic container or envelope of defined shape which may be easily held by a robot, which may be loaded at a central filling station and subsequently linked with a feeding module which includes drive means for advancing the tape reel. As an alternative, if the placement machine itself is provided with tape driving mechanisms, then the cartridge module could be directly inserted into the placement machine along a slot thereof. An example of a cartridge and feeder arrangement is described for example in DE 10 2019 127 299.8. In such systems, the feeder unit may be used to drive the carrier tape located within a cartridge unit so that components located within pockets of the carrier tape are moved to a picking region where a placement head of a placement machine can access the components. The picking region could be located within the cartridge or within the feeder, depending on the particular design.

For the operation of the placement machine it is necessary to be able to supply feeders (and/or cartridges depending on the set-up), including respective carrier tapes, to the placement machine.

Such retooling (i.e. fitting of different feeders/cartridges) is currently a manual process that requires a high level of personnel input.

In today's standard manual replenishment method, known as “splicing”, the carrier tape from which the placement machine picks up the component is manually connected to a new tape. In this process, the old tape is unwound from its reel, connected (spliced) to the new carrier tape and rolled onto the new reel.

This process allows the replenishment to take place before it is needed. The refilling does not need to take place at an exact time, but within a given period. This period is calculated and observed by software, such as the Siplace Line Monitor for example. This ensures a certain decoupling of the processes, whereby a continuous order situation can be created for the replenishment respectively filling process. In this way, load peaks and lulls can balance each other out to a certain extent.

For some years now, considerable efforts have been made to automate material replenishment and changeover.

As specific background art may be mentioned EP3419402A1. As described in this document, an external exchanging device may be provided to transfer a feeder, which includes both feeding capability and material storage, between a storage location and an operational location, with the exchanging device operable to move along a production line with one or more placement machines parallel to the direction of workpiece throughput. The exchanging device is operative to translate along a rail mounted along the production line, and is supported by the rail (for this reason the device may be termed a “rail-guided vehicle”). Such an approach has various advantages, for example using a machine-mounted rail avoids any problems that may arise due to imperfections in the floor surface, since the exchanging device is held at a fixed vertical position relative to the placement machines, and furthermore a high level of positioning accuracy along the production line is possible. One advantage of such a system is that the rail-guided vehicle may draw power directly and potentially continuously from the placement machine. However, there are also various disadvantages associated with such a system. For example, it is necessary to use a dedicated exchanging device for each side of the production line, which may limit how close adjacent lines may be placed. The described system also lacks flexibility, and for example cannot manage cartridge-based feeding systems. It has been found that the system is relatively slow, and is also expensive due to the large requirement for dedicated equipment for each production line.

It has been recognised that a more flexible and potentially cheaper solution may be to equip an automatic-guided vehicle (AGV) with a feeder/cartridge replacement mechanism. As is well-known in the art per se, AGVs are small mobile robot devices, typically movable across a floor by means of a wheeled chassis, with at least a degree of autonomy. AGVs are available from many manufacturers (and hence relatively inexpensive and with a likelihood that a production line operator may already possess suitable AGVs), and are typically provided with an upper platform which can carry job-specific equipment.

Such approaches permit automated or automatic replenishment through feeder exchange, rather than the manual splicing method described above. In such automated processes, the tape and reel are stored and transported inside the feeder. An automatic handling system handles the feeder directly, with the reel located within the feeder. In contrast to the manual splicing method, in which reels and tapes are handled separately, in an automated process a constant and defined feeder interface can be used for handling, which simplifies the handling. A key part of the automatic handling system is the exchange mechanism which is operative to transfer feeders between the placement machine and a separate storage location.

To refill material at a placement machine, a feeder is pulled out of its track within the machine by an automatic handling system/exchange mechanism, and a new feeder replaces the old feeder at the same slot. To ensure that all components of a tape are used, a slot should only be refilled when all components of a feeder have been picked by the placement machine. This means that advanced refilling at the same track (which is possible in a manual splicing process) is no longer possible.

With such an automated process, there are two main causes of machine downtime, in which picking cannot be performed:
i) Firstly, no component can be picked up from a feeder associated with a track while feeders for that track are being exchanged. These downtimes can be minimized by exchanging the feeders more rapidly.
ii) In addition, downtimes can occur if the automatic handling system does not change the feeder on a track at the right time, i.e. too late, so that the feeder runs out of components before exchange. This can happen when, for example, several feeders (either at a placement machine or on a production line including one or more placement machines) become depleted at the same time. In this case the feeders can only be replaced one after the other, assuming there is only a single automatic handling system at the line. Providing additional automatic handling machines at a line may reduce this type of downtime, however this problem may still arise if more than two feeders become depleted at the same time. In addition, providing additional automatic handling machines significantly increases cost to the production line operator.

There have been various initiatives to minimise the downtimes incurred using automated processes. For example, EP23171095.5 by the present applicant, and U.S. Pat. No. 11,464,145B2 and WO-A1-2020039543, describe methods in which the new or replacement feeder (second feeder) is placed on a spare track within the same placement machine. After the first feeder runs out of components the machine can pick components from the second feeder. This type of method can significantly reduce downtime, and may prevent the machine from coming to a halt if properly implemented.

Such a method is schematically shown in FIGS. 1A-1F.

FIG. 1A shows a placement machine 1 with a placement head 2 which is operable to pick components from feeder modules located in any slots of the placement machine 2. Here, five slots are shown-in practice there would typically be many more than this. Of these five, three slots 3A, 3B and 3C are ‘preferred slots’, which are well-positioned for an efficient placement operation, while slots 4A, 4B are ‘spare slots’, which are not well-positioned and so lead to inefficiencies in a placement operation when components are picked from a feeder module in such a spare slot. For example, if workpieces (not shown) which undergo a placement operation travel through the placement machine 1 in a transport direction T, the placement location of these workpieces within the placement machine 1 may be proximate slots 3A-3C, and so picking from feeders in spare slots 4A, 4B would necessitate additional travel, and associated additional travel time, of the placement head 2 between the feeder module and the workpiece.

The position of placement head 2 next to slot 3C shows that picking is currently taking place from a feeder module, i.e. a first feeder module ‘A’, located in that slot. Here, the first feeder module A has sufficient components, i.e. they are not yet depleted by the placement operation to the extent that replenishment becomes necessary or desirable.

FIG. 1B shows the commencement of a replenishment operation, which is triggered when the first feeder module A reaches a predefined depletion level, illustrated by the diagonal line across first feeder module A. At this point, a mobile robot 5 is sent to the placement machine 2 and aligns itself proximate the slots 3A-C, 4A, B. The mobile robot 5 includes a storage 6 for temporarily retaining at least two feeder modules. The storage 6 is movable relative to the base of the mobile robot 5 along an axis X, which, when the mobile robot 5 is located to engage with the placement machine 1, is generally parallel to the transport direction T. This relative movement permits the storage 6, and thus the retained feeder modules, to be aligned, parallel to the transport direction T, as required relative to the slots 3A-C, 4A, 4B.

It should be noted that there are other possibilities for achieving such alignment between retained feeder modules and the slots 3A-C, 4A, 4B. For example, the mobile robot 5 itself may be capable of accurate movement along the X-axis, in which case no relative motion of the storage 6 is required. Alternatively, an exchange mechanism (see below) may be provided which is capable of moving feeder modules parallel to the X-axis during transfer between the storage 6 and placement machine 1.

As shown in FIG. 1B, the storage 6 includes a plurality, here three, of storage slots 7A-C, each storage slot 7A-C configured to releasably receive a feeder module in use. As shown, a second feeder module B is received within storage slot 7B—this second feeder module B contains the same type of component as the first feeder module A. The storage 6 aligns with the placement machine 1 so that the storage slot 7B aligns with a spare slot, in this case 4B. If necessary, the storage 6 is moved along the X-axis to achieve such alignment (not shown). During this stage, picking by the placement head 2 continues from the first feeder module A.

As shown in FIG. 1C, the second feeder module B is then transferred from the storage slot 7B to the spare slot 4B, by an exchange mechanism 8. The exchange mechanism 8 is not shown in detail in the figures, but comprises a mechanical interface capable of transferring feeder modules, horizontally and orthogonally to the X-axis, between the storage 6 and the placement machine 1 in both directions, for example by engaging with a profiled section of the feeder module. A simple type of exchange mechanism 8 may for example comprise a paddle which can engage with a recess provided on a feeder module, the paddle being mounted to a drive belt which can be driven in either direction and so push or pull the feeder module linearly between the storage 6 and placement machine 1. Exemplary exchange mechanisms are described in DE102021117281B3, DE102021119314B3 and EP2319433.5 for example. The exchange mechanism 8 may be located on the mobile robot 5, or on the placement machine 1, or as a separate unit. During this stage, picking by the placement head 2 continues from the first feeder module A, until the first feeder module A is fully depleted.

As shown in FIG. 1D, when the first feeder module A is fully depleted (as shown by the two crossed lines in feeder module A), the placement head 2 commences picking components from the second feeder module B in spare slot 4B.

As shown in FIG. 1E, the mobile robot 5 is then sent to the placement machine 1. The storage 6 is moved along the X-axis so that an empty storage slot, here 7B, is aligned with slot 3C. During this stage, picking by the placement head 2 continues from the second feeder module B.

As shown in FIG. 1F, the exchange mechanism 8 then transfers the empty first feeder module A from slot 3C to storage slot 7B. During this stage, picking by the placement head 2 continues from the second feeder module B.

It can be seen that during the steps shown in FIGS. 1D to 1F, the placement head 2 picks from the second feeder module B while it is in the spare slot 4B. This is a disadvantage of such methods. Usually, the feeder module located on each slot are carefully chosen to optimise placement speed, so that, for example, components which are placed in large numbers on a board may be located at slots which are a small distance from a placement head's nominal ‘home’ position, thus minimising travel time of the placement head 2. If the feeder module is instead located in a spare slot then clearly its location might not be so optimised.

This lack of optimisation may be corrected by subsequently moving the second feeder module B to the optimal slot, i.e. to the original location of the first feeder module A (here slot 3C), once the first feeder module A is empty. This is schematically shown in FIGS. 1G-1J. As will be clear from the description below, this movement will necessitate downtime in which no component associated with the feeder module may be picked. There is at least some flexibility as to when the movement occurs, so it may be possible to perform this at a relatively convenient time, reducing impact on throughput, but nevertheless this downtime is unavoidable.

As shown in FIG. 1G, the storage 6 moves along the X-axis, to the left as shown, until an empty storage slot, here 7C, aligns with spare slot 4B. During this stage, picking by the placement head 2 continues from the second feeder module B.

As shown in FIG. 1H, the exchange mechanism 8 then transfers the second feeder module B into slot 7C of the storage 6. During this stage, no picking can occur.

As shown in FIG. 1I, the storage 6 moves along the X-axis, to the right as shown, until the storage slot 7C aligns with slot 3C. The exchange mechanism 8 can then transfer the second feeder module B into slot 3C. During this stage, no picking can occur.

Finally, as shown in FIG. 1J, the placement head 2 can recommence picking from the second feeder module B in slot 3C. The mobile robot 5 is free to move off as required, and in due course deliver the empty first feeder module A to a collection station (not shown) for refilling.

The present invention seeks to provide an automatic replenishment system and method in which downtimes are minimised, and yet may still be administered by using an economically-reasonable number of automatic handling machines or exchange units.

In accordance with the present invention this aim is achieved by a new procedure for replacing depleted feeder modules, and thus supplying SMT-components within feeder modules to a placement machine.

### SUMMARY OF THE INVENTION

In accordance with a first aspect of the present invention there is provided a method for supplying SMT-components within feeder modules to a placement machine during an SMT-placement operation, the placement machine comprising a plurality of slots, each slot configured to releasably receive a feeder module in use, and a first slot of the plurality of slots having a first feeder module received therein which contains a plurality of SMT-components which becomes depleted during the SMT-placement operation, the method comprising the steps:
i) providing an exchange unit, the exchange unit comprising a storage for temporarily retaining at least two feeder modules, wherein the storage is provided with a second feeder module which contains the same type of SMT-components as the first feeder module,
ii) transferring the first feeder module from the first slot into the storage before the first feeder module is fully depleted of SMT-components,
iii) transferring the second feeder module from the storage to the first slot, and
iv) transferring the first feeder module from the storage to a second slot of the plurality of slots of the placement machine.

In accordance with a second aspect of the present invention there is provided a method for replacing depleted feeder modules at a placement machine during an SMT-placement operation, the placement machine comprising a plurality of slots, each slot configured to releasably receive a feeder module in use, and a first slot of the plurality of slots having a first feeder module received therein which contains a plurality of SMT-components which becomes depleted during the SMT-placement operation, the method comprising the steps:
i) providing an exchange unit, the exchange unit comprising:
   a storage for temporarily retaining at least two feeder modules, wherein the storage is provided with a second feeder module which contains the same type of SMT-components as the first feeder module,
ii) transferring the first feeder module from the first slot into the storage before the first feeder module is fully depleted of SMT-components,
iii) transferring the second feeder module from the storage to the first slot, and
iv) transferring the first feeder module from the storage to a second slot of the plurality of slots of the placement machine.

Other specific aspects and features of the present invention are set out in the accompanying claims.

For the purposes of the present invention, the term “feeder module” means either:
a) a feeder, i.e. a single module that carries a component tape reel and driving means for advancing the tape reel, or
b) a cartridge module which carries a component tape reel but no driving means, for engagement either with a separate feeding module or directly with a placement machine that includes tape driving means.

The term “mobile robot” as used herein encompasses automated guided vehicles (AGVs), rail-guided vehicles (RGV) which, as described above, are mobile robots movable along a rail carried by or proximate to a placement machine, autonomous intelligent vehicles (AIVs) and the like.

### BRIEF DESCRIPTION OF THE DRAWINGS

The invention will now be described with reference to the accompanying drawings (not to scale), in which:

FIGS. 1A-J schematically show steps of a known feeder module replacement method; and

FIGS. 2A-J schematically show steps of a feeder module replacement method in accordance with the present invention.

### DETAILED DESCRIPTION OF THE PREFERRED EMBODIMENTS OF THE INVENTION

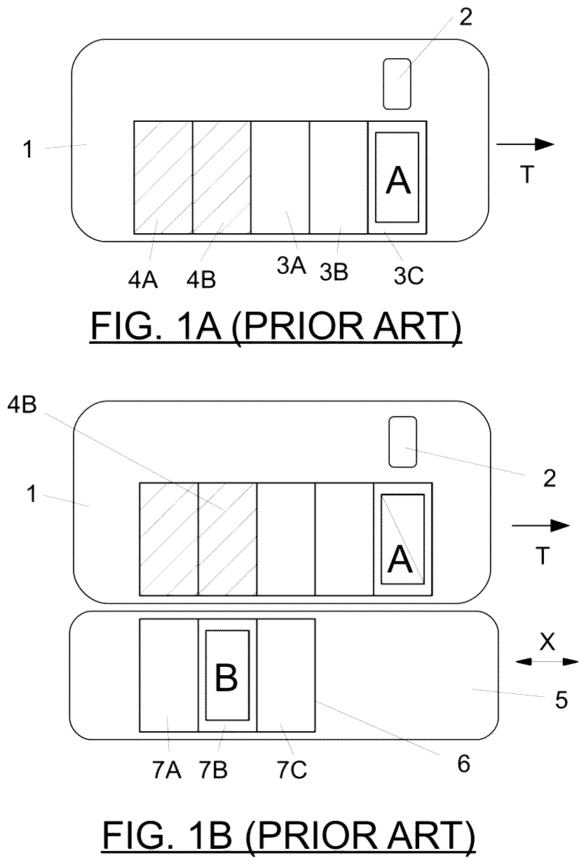

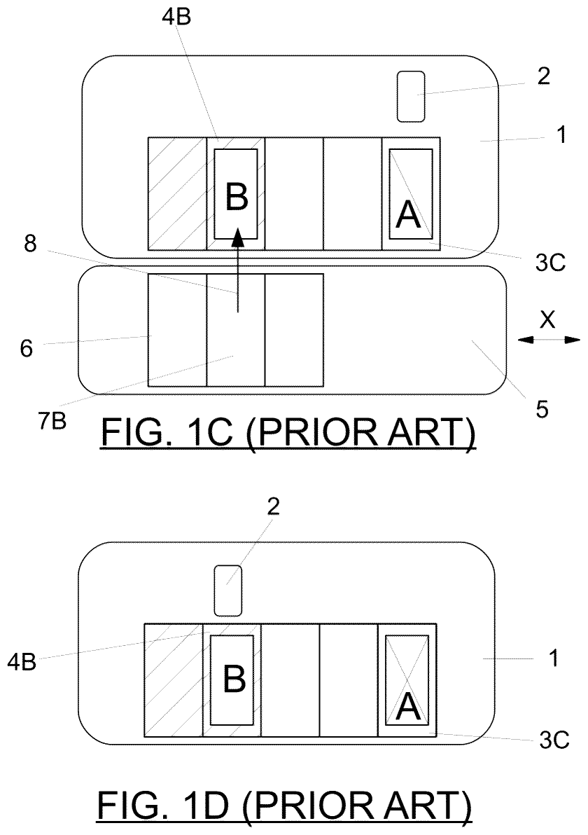

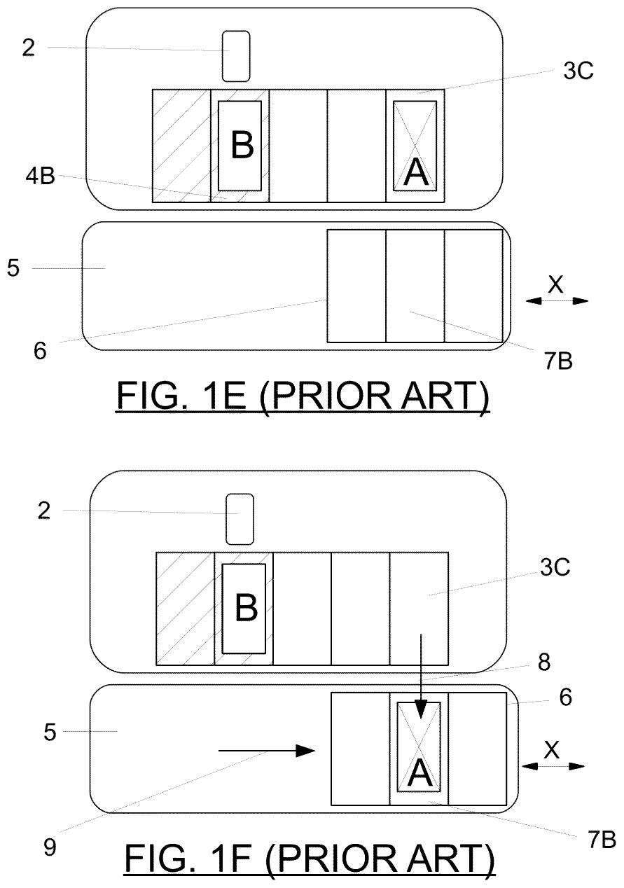

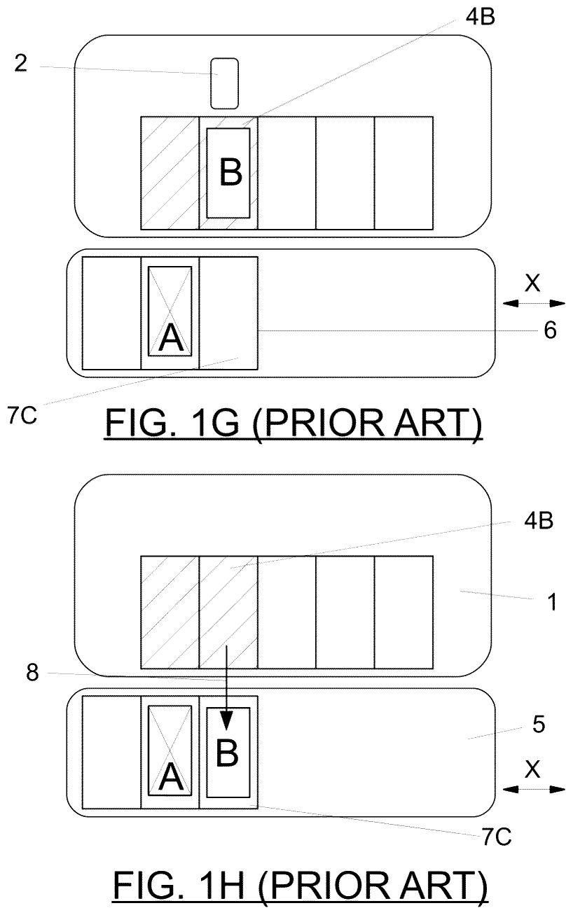

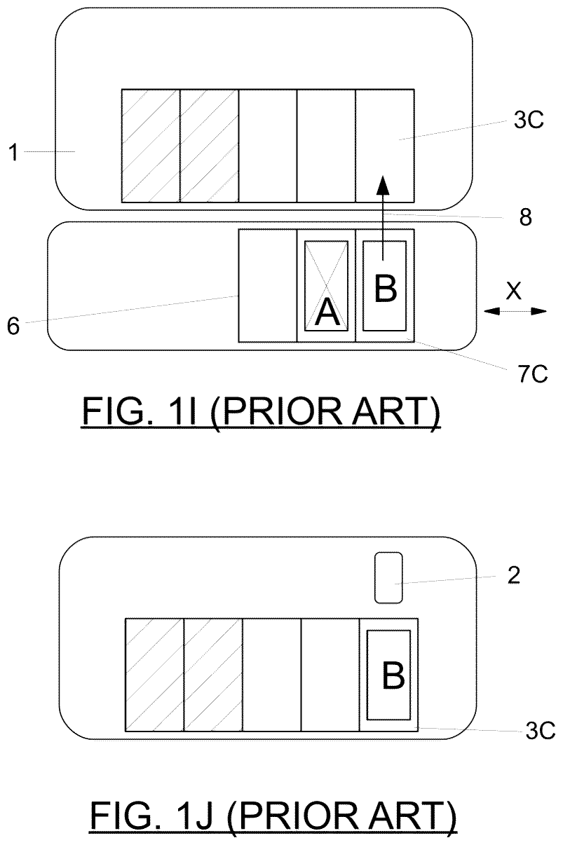

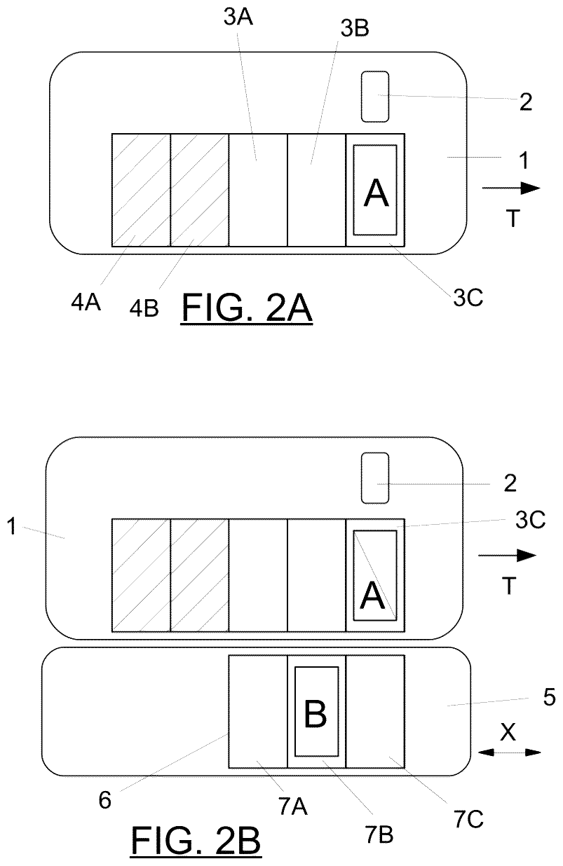

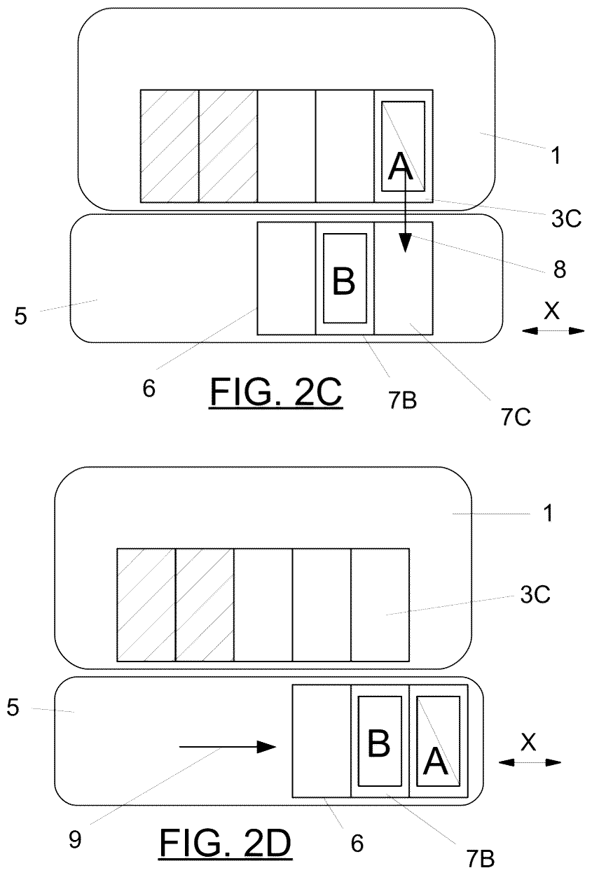

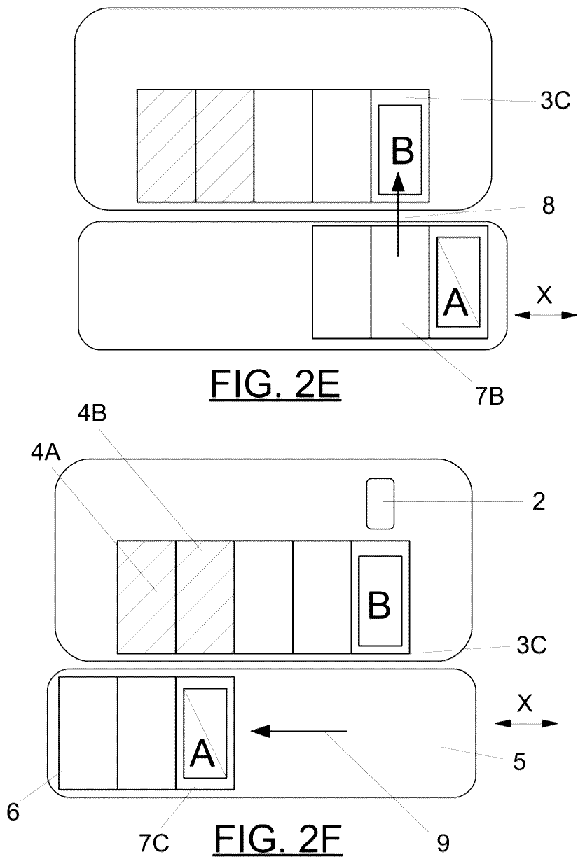

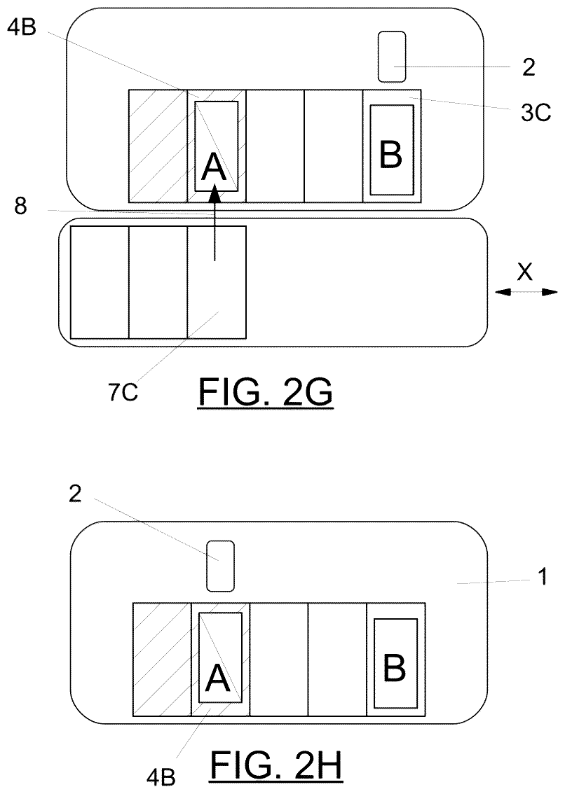

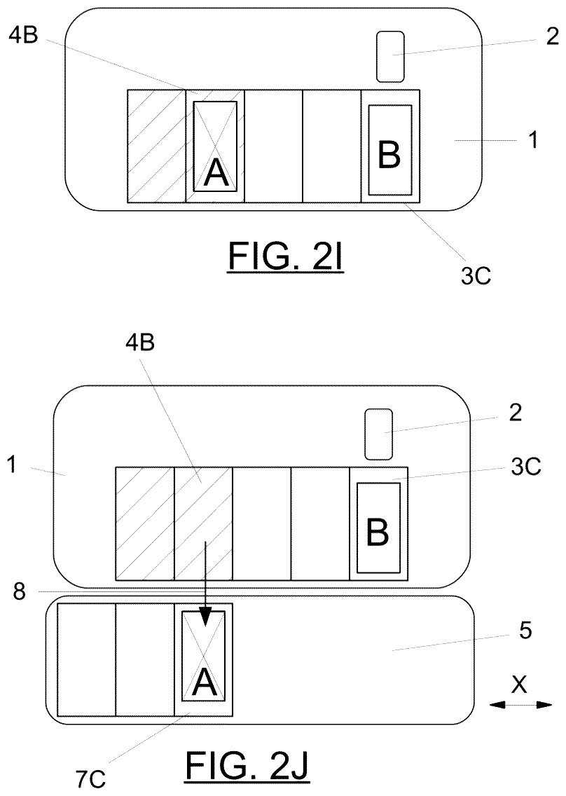

FIGS. 2A-J schematically show steps of a feeder module replacement method in accordance with the present invention. These may conveniently use similar apparatus to that shown and described above with reference to FIGS. 1A-J, and so the relevant reference numbers are retained for simplicity.

FIG. 2A shows a placement machine 1 with a placement head 2 which is operable to pick components from feeder modules located in any slots of the placement machine 2. Here, five slots are shown—in practice there would typically be many more than this. Of these five, three slots 3A, 3B and 3C are ‘preferred slots’, which are well-positioned for an efficient placement operation, while slots 4A, 4B are ‘spare slots’, which are not well-positioned and so lead to inefficiencies in a placement operation when components are picked from a feeder module in such a spare slot. For example, if workpieces (not shown) which undergo a placement operation travel through the placement machine 1 in a transport direction T, the placement location of these workpieces within the placement machine 1 may be proximate slots 3A-3C, and so picking from feeder modules in spare slots 4A, 4B would necessitate additional travel, and associated additional travel time, of the placement head 2 between the feeder module and the workpiece.

The position of placement head 2 next to slot 3C shows that picking is currently taking place from a feeder module, i.e. a first feeder module ‘A’, located in that slot. Here, the first feeder module A has sufficient components, i.e. they are not yet depleted by the placement operation to the extent that replenishment becomes necessary or desirable.

FIG. 2B shows the commencement of a replenishment operation, which is triggered when the first feeder module A reaches a predefined depletion level, illustrated by the diagonal line across first feeder module A. There are various methods by which the predefined level of depletion of the feeder module A may be determined. For example:
i) a run-out-time for the first feeder module A may be determined, after which time the first feeder module A becomes fully depleted of SMT-components. The predefined level of depletion may then be defined as the level of depletion occurring after a predefined subrange of the determined run-out-time. For example, if the predefined level of depletion is set to occur after 70% of the run-out-time, and it is determined that the run-out-time for a feeder module is ten minutes, then the predefined level of depletion will occur after seven minutes. At this time the replenishment operation is triggered. The run-out-time for the feeder module A may be determined by, for example, having knowledge of the initial number of SMT-components retained by the feeder module A, and analysing the usage of those SMT-components during a placement operation, by counting the number of SMT-components picked, or by analysing the number of those SMT-components required for each workpiece to be placed on and counting the number of workpieces thus placed; or
ii) the number of SMT-components remaining in the first feeder module A may be determined, and the predefined level of depletion is set when the number of remaining SMT-components retained by the feeder module A falls below a set number. Again, the number of SMT-components remaining in the first feeder module A may be determined by having knowledge of the initial number of SMT-components retained by the feeder module A, and analysing the usage of those SMT-components during a placement operation, by counting the number of SMT-components picked, or by analysing the number of those SMT-components required for each workpiece to be placed on and counting the number of workpieces thus placed. The replenishment operation is commenced when the determined number of SMT-components remaining in the first feeder module is below a threshold value.

At this point, a mobile robot 5, which is the exchange unit used in this embodiment, is sent to the placement machine 2 and aligns itself proximate the slots 3A-C, 4A, B. The mobile robot 5 includes a storage 6 for temporarily retaining at least two feeder modules. The storage 6 is movable relative to the base of the mobile robot 5 along an axis X, which, when the mobile robot 5 is located to engage with the placement machine 1, is generally parallel to the transport direction T. This relative movement permits the storage 6, and thus the retained feeder modules, to be aligned, parallel to the transport direction T, as required relative to the slots 3A-C, 4A, 4B.

It should be noted that there are other possibilities for achieving such alignment between retained feeder modules and the slots 3A-C, 4A, 4B. For example, the mobile robot 5 itself may be capable of accurate movement along the X-axis, in which case no relative motion of the storage 6 is required. Alternatively, an exchange mechanism (see below) may be provided which is capable of moving feeder modules parallel to the X-axis during transfer between the storage 6 and placement machine 1.

As shown in FIG. 2B, the storage 6 includes a plurality, here three, of storage slots 7A-C, each storage slot 7A-C configured to releasably receive a feeder module in use. As shown, a second feeder module B is received within storage slot 7B—this second feeder module B contains the same type of component as the first feeder module A. The storage 6 aligns with the placement machine 1 so that an empty the storage slot, here storage slot 7C, aligns with the slot 3C, in Which the first feeder module A is located. If necessary, the storage 6 is moved along the X-axis to achieve such alignment (not shown). During this stage, picking by the placement head 2 continues from the first feeder module A.

As shown in FIG. 2C, the first feeder module A is then transferred from the slot 3C to the storage slot 7C, by an exchange mechanism 8. The exchange mechanism 8 is not shown in detail in the figures, but comprises a mechanical interface capable of transferring feeder modules, horizontally and orthogonally to the X-axis, between the storage 6 and the placement machine 1 in both directions, for example by engaging with a profiled section of the feeder module. A simple type of exchange mechanism 8 may for example comprise a paddle which can engage with a recess provided on a feeder module, the paddle being mounted to a drive belt which can be driven in either direction and so push or pull the feeder module linearly between the storage 6 and placement machine 1. Exemplary exchange mechanisms are described in DE102021117281B3, DE102021119314B3 and EP2319433.5 for example. The exchange mechanism 8 may be located on the mobile robot 5, or on the placement machine 1, or as a separate unit. During this stage, no picking by the placement head 2 is possible.

As shown in FIG. 2D, the storage 6 is moved along the X-axis so that the storage slot 7B, which retains the full second feeder module B, is aligned with the now empty slot 3C. During this stage, no picking by the placement head 2 is possible.

As shown in FIG. 2E, the exchange mechanism 8 then transfers the full second feeder module B from storage slot 7B to slot 3C. During this stage, no picking by the placement head 2 is possible until the second feeder module B is fully transferred to slot 3C.

As shown in FIG. 2F, the storage 6 is moved along the X-axis so that storage slot 7C, which retains the partially depleted first feeder module A, is aligned with a spare slot, in this case 4B, which provides slightly more economical picking than for the other spare slot 4A. During this stage, picking by the placement head 2 may continue from the second feeder module B if required.

As shown in FIG. 2G, the exchange mechanism 8 then transfers the partially depleted first feeder module A from storage slot 7C to spare slot 4B. During this stage, picking by the placement head 2 continues from the second feeder module B.

As shown in FIG. 2H, the placement head 2 can recommence picking from the first feeder module A in spare slot 4B. The mobile robot 5 is free to move off as required.

As shown in FIG. 2I, once the first feeder module A is fully depleted (as shown by the two crossed lines in feeder module A), the placement head 2 can recommence picking from the second feeder module B in slot 3C.

Finally, as shown in FIG. 2J, the mobile robot 5 is sent into position proximate the placement machine 1, and the storage 6 moved along the X-axis so that an empty storage slot, in this case 7C, aligns with the spare slot 4B. The exchange mechanism 8 then transfers the empty first feeder module A from spare slot 4B to storage slot 7C. During this stage, picking by the placement head 2 continues from the second feeder module B. The mobile robot 5 is free to move off as required, and in due course deliver the empty first feeder module A to a collection station (not shown) for refilling. This step can be performed when convenient-since the second feeder module B still has a good level of filling, there is no immediate urgency to collecting the empty first feeder module A. This means that the mobile robot 5 is available to perform other, perhaps more urgent, operations in the meantime.

It can be seen that the present methodology provides various advantages over the previous method shown in FIG. 1:
The mobile robot can perform a refill task before a feeder module runs out of components. Thereby the time dependency can be reduced and the performance requirements for the replenishment process are lower. Simulations have shown that for smartphone customers with lines with eleven placement machines, two robots are needed to perform all replenishment tasks in time using the previous method where the feeder module is exchanged on time. Using the present method, the number of robots could be reduced to one;
The reduced time dependency makes the replenishment process more robust against disturbances of the automatic handling and the production flow. An example of such a machine disturbance is if there are two feeder module exchange events in short time period, so that a forecast has to decide which feeder module should be exchanged first. However, disturbances like pick errors can cause the forecast to be incorrect. A mobile robot may therefore be sent to a wrong location, resulting in longer machine stoppages. The same applies to disturbances affecting the replenishment process such as the presence of human operators in the aisle;
The reduced time dependency allows a reduction in the forecast accuracy of the feeder module exchange events;
The mobile robot is released from the line; since more spare tracks are used on the line, the mobile robot will gain a larger block of ‘idle time’, which can be used for supporting other lines' tasks, changeover, battery charging, etc.; and
There is a shorter track-unavailable-period compared to the previous method.

The above-described embodiments are exemplary only, and other possibilities and alternatives within the scope of the invention will be apparent to those skilled in the art. For example, several steps can be combined. For instance, at the same time as, or directly before or after, the mobile robot transfers the partially depleted first feeder module to the spare slot, it can pick up any empty feeder modules that may be present in other spare slots, for example those emptied during a previous replenishment operation.

In the above-described embodiments, the exchange unit comprised a mobile robot including a storage. However, the invention is not so limited, and other types of exchange unit, each including a storage, may be used. For example, exchange units are known which are at least temporarily retained at the placement machine. Such exchange units may be placed at the placement machine by a mobile robot, which can move away while the exchange unit effects the required transfer of feeder modules, or may be able to travel along the side of placement machines as required (such as so-called ‘rail-guided vehicles’), or which are simply placed next to a placement machine, optionally by a human operator (similar to well-known changeover tables). In all cases, the exchange mechanism may be provided either as part of the exchange unit, or as part of the placement machine, or as a separate unit.

### REFERENCE NUMERALS USED

1—Placement machine
2—Placement head
3A-C—Preferred slots
4A, B—Spare slots
5—Mobile robot
6—Storage
7A-C—Storage slots
8—Exchange mechanism
9—Storage conveyor
A—First feeder module
B—Second feeder module
T—Transport direction
X—Horizontal axis

1. A method for supplying SMT-components within feeder modules to a placement machine during an SMT-placement operation, the placement machine comprising a plurality of slots, each slot configured to releasably receive a feeder module in use, and a first slot of the plurality of slots having a first feeder module received therein which contains a plurality of SMT-components which becomes depleted during the SMT-placement operation, the method comprising the steps:
i) providing an exchange unit, the exchange unit comprising a storage for temporarily retaining at least two feeder modules, wherein the storage is provided with a second feeder module which contains the same type of SMT-components as the first feeder module,
ii) commencing a replenishment operation comprising transferring the first feeder module from the first slot into the storage before the first feeder module is fully depleted of SMT-components,
iii) continuing the replenishment operation by transferring the second feeder module from the storage to the first slot, and
iv) transferring the first feeder module from the storage to a second slot of the plurality of slots of the placement machine.

2. The method of claim 1, wherein step i) comprises providing an exchange mechanism operable to transfer a feeder module from a slot of the plurality of slots of the placement machine into the storage, and to transfer a feeder module from the storage into a slot of the plurality of slots of the placement machine, and in steps ii), iii) and iv), the first and second feeder modules are transferred by the exchange mechanism.

3. The method of claim 2, wherein the storage comprises a plurality of storage slots, each storage slot configured to releasably receive a feeder module in use, and wherein the exchange mechanism is operable to transfer a feeder module from a slot of the plurality of slots of the placement machine into a storage slot, and to transfer a feeder module from a storage slot into a slot of the plurality of slots of the placement machine.

4. The method of claim 2, wherein the exchange unit comprises the exchange mechanism.

5. The method of claim 2, wherein the placement machine comprises the exchange mechanism.

6. The method of claim 1, wherein step iii) comprises using a placement head of the placement machine to pick SMT-components from the second feeder module in the first slot.

7. The method of claim 1, comprising the step:
v) using a placement head of the placement machine to pick SMT-components from the first feeder module in the second slot.

8. The method of claim 7, comprising the step:
vi) when the first feeder module is fully depleted of SMT-components, using the placement head of the placement machine to pick SMT-components from the second feeder module in the first slot.

9. The method of claim 8, comprising the step:
vii) transferring the fully depleted first feeder module from the second slot into the storage.

10. The method of claim 1, wherein step ii) comprises determining a run-out-time for the first feeder module, at which time the first feeder module becomes fully depleted of SMT-components, and commencing the replenishment operation within a predefined subrange of the determined run-out time.

11. The method of claim 1, wherein step ii) comprises determining the number of SMT-components remaining in the first feeder module, and commencing the replenishment operation when the determined number of SMT-components remaining in the first feeder module is below a threshold value.

12. The method of claim 1, wherein the exchange unit comprises a mobile robot.

13. The method of claim 12, wherein the mobile robot comprises one of group consisting of automated guided vehicles, rail-guided vehicles, autonomous intelligent vehicles.

14. The method of claim 1, wherein the feeder module comprises a feeder.

15. The method of claim 1, wherein the feeder module comprises a cartridge module.

16. A method for replacing depleted feeder modules at a placement machine during an SMT-placement operation, the placement machine comprising a plurality of slots, each slot configured to releasably receive a feeder module in use, and a first slot of the plurality of slots having a first feeder module received therein which contains a plurality of SMT-components which becomes depleted during the SMT-placement operation, the method comprising the steps:
i) providing an exchange unit, the exchange unit comprising:
a storage for temporarily retaining at least two feeder modules, wherein the storage is provided with a second feeder module which contains the same type of SMT-components as the first feeder module,
ii) transferring the first feeder module from the first slot into the storage before the first feeder module is fully depleted of SMT-components,
iii) transferring the second feeder module from the storage to the first slot, and
iv) transferring the first feeder module from the storage to a second slot of the plurality of slots of the placement machine.
